(19) United States
(12) Patent Application Publication
(10) Pub. No.: US 2025/0105758 A1
(43) Pub. Date: Mar. 27, 2025

(54) THREE-LEVEL POWER SEMICONDUCTOR MODULE AND ARRANGEMENT THEREWITH

(71) Applicant: SEMIKRON DANFOSS ELEKTRONIK GMBH & CO. KG, NUREMBERG (DE)

(72) Inventors: Peter BECKEDAHL, Oberasbach (DE); Andreas WOHLFART, Nuremberg (DE); Mathias Spang, Nuremberg (DE)

(73) Assignee: SEMIKRON DANFOSS ELEKTRONIK GMBH & CO. KG, NUREMBERG (DE)

(21) Appl. No.: 18/898,264

(22) Filed: Sep. 26, 2024

(30) Foreign Application Priority Data
Sep. 26, 2023 (DE) 10 2023 126 065.0

(51) Int. Cl. H02M 7/487; H01L 25/07; H02M 7/00

(52) U.S. Cl. CPC H02M 7/487; H02M 7/003; H01L 25/072

(57) ABSTRACT

A three-level power semiconductor module with a housing, with a switching device, with a first, a second and a third DC voltage terminal element, and with an AC voltage terminal element. The switching device has a normal direction and is in the form of a TNPC circuit arrangement, which has a DC branch with an upper first switch whose power input is connected to a high potential of a DC voltage source, with a lower fourth switch whose power output is connected to a low potential of a DC voltage source and with a centre tap and a T branch with a second switch whose power input is connected to an intermediate potential and with a third switch, connected in series with the second switch, whose power input is connected to the centre tap, wherein the focal points of the first and fourth switch lie in the direction from the group of DC voltage terminals to the AC voltage terminal on a first straight line and the focal points of the second and third switch lie in the direction from the group of DC voltage terminals to the AC voltage terminal on a second straight line adjacent to the first straight line.

### CROSS REFERENCE TO RELATED APPLICATIONS

This application relates to and claims priority to DE 10 2023 126 065.5 filed Sep. 26, 2023, the entire contents of which are incorporated herein fully by reference.

### FIGURE SELECTED FOR PUBLICATION

FIG. 2.

### BACKGROUND OF THE INVENTION

### Field of the Invention

The invention describes a three-level power semiconductor module with a housing, with a switching device, with a first, a second and a third DC voltage terminal element and with an AC voltage terminal element and in the form of a TNPC circuit arrangement, which has a DC branch with an upper first switch whose power input is connected to a high potential of a DC voltage source, with a lower fourth switch whose power output is connected to a low potential of a DC voltage source and with a centre tap and a T branch with a second switch whose power input is connected indirectly or directly to an intermediate potential and with a third switch, connected in series with the second switch, whose power input is connected indirectly or directly to the centre tap. The invention furthermore describes an arrangement with a plurality of such three-level power semiconductor modules.

### Description of the Related Art

Document DE 10 2017 115 883 A1 discloses a submodule and an arrangement therewith, wherein the submodule comprises a switching device with a substrate and conductor tracks arranged thereon. The submodule comprises a first and a second DC voltage conductor track and a first and a second DC voltage terminal element electrically conductively connected thereto, as well as an AC voltage conductor track and an AC voltage terminal element electrically conductively connected thereto. The submodule further comprises a shaped insulator body, which encloses the switching device in a frame-like manner. In this case, the first DC voltage terminal element rests with a first contact section on a first contact body of the shaped insulator body, the AC voltage terminal element rests with a second contact section on a second contact body of the shaped insulator body. A first clamping device is designed to extend through a first opening of the first contact body in an electrically insulated manner and to form an electrically conductive clamped connection between the first DC voltage terminal element and an associated first DC voltage connection element, and a second clamping device is designed to extend through a second opening of the second contact body in an electrically insulated manner and to form an electrically conductive clamped connection between the AC voltage terminal element and an associated AC voltage connection element.

### Aspects and Objects of the Invention

At least one of the objects of the present invention is to provide an improvement over the related art.

The invention is based on the object of developing the prior art such that the switches of a switching device in the form of a three-level circuit arrangement in half-bridge topology are arranged in a housing with DC voltage terminal elements on a narrow side and an AC voltage terminal element on an opposite narrow side in such a way that inductances during commutation are minimized.

This object is achieved according to the invention by a three-level power semiconductor module with a housing, with a switching device, with a first, a second and a third DC voltage terminal element which form a group, and with an AC voltage terminal element, wherein the switching device has a normal direction and is in the form of a TNPC circuit arrangement, which has a DC branch with an upper first switch whose power input is connected to a high potential of a DC voltage source, with a lower fourth switch whose power output is connected to a low potential of a DC voltage source and with a center tap and a T branch with a second switch whose power input is connected indirectly or directly to an intermediate potential and with a third switch, connected in series with the second switch, whose power input is connected indirectly or directly to the center tap, wherein the focal points of the first and fourth switch lie in the direction from the group of DC voltage terminals to the AC voltage terminal on a first straight line and the focal points of the second and third switch lie in the direction from the group of DC voltage terminals to the AC voltage terminal on a second straight line adjacent, preferably parallel, to the first straight line.

The term “switching device” should be understood to mean, in particular, one or more customary power electronics substrates with customary power semiconductor components arranged thereon and a customary internal connecting device formed, in particular, as wire bond connections or as a foil stack of conductive and insulating foils which are structured in themselves.

The term “direct connection to a potential” is understood to mean, in particular, that a terminal element of a power semiconductor module is directly connected to a conductor track on which a switch is arranged. The term “indirect connection to a potential” is understood to mean, in particular, that a terminal element of a power semiconductor module is connected via a further component, for example an internal connecting device, to a conductor track on which a switch is arranged.

The term “adjacent straight lines” should be understood to mean, in particular, two straight lines which lie in one plane and intersect one another at a point which does not lie inside the periphery of the power semiconductor module.

A “straight line from the group of DC voltage terminals to the AC voltage terminal” should be understood to mean a straight line which extends, in projection in the normal direction, both through the group as a whole and through the AC voltage terminal, that is to say intersects the respective areas.

It is preferred if the current-carrying capacity of all the switches is identical or the current-carrying capacity of the first and fourth switch is greater than that of the second and third switch, respectively.

It is particularly preferred if the respective switch is in the form of a power semiconductor component or a group of power semiconductor components connected in parallel, wherein the respective power semiconductor component is in the form of an IGBT, preferably with antiparallel-connected diodes, or a MOS-FET, in particular a SiC-MOS-FET, or an HEMT, in particular a GaN-HEMT.

It may also be advantageous if the focal points form the corners of a trapezoid or parallelogram.

It may be preferred if respective connection surfaces of the DC voltage terminal elements have an identical normal direction, are arranged next to one another in projection in the normal direction and

the third connection surface of the third DC voltage terminal element lies in a first plane and the first connection surface of the first DC voltage terminal element lies in a second plane parallel to the first when viewed in the normal direction. Here, it may be preferred if the second connection surface of the second DC voltage terminal element lies in the second plane when viewed in the normal direction.

Here, it may be preferred, on the one hand, if the first DC voltage terminal element is intended to be connected to the high potential, wherein the second DC voltage terminal element is intended to be connected to the intermediate potential, and wherein the third DC voltage terminal element is intended to be connected to the low potential.

Here, it may be preferred, on the other hand, if the first DC voltage terminal element is intended to be connected to the low potential, wherein the second DC voltage terminal element is intended to be connected to the intermediate potential, and wherein the third DC voltage terminal element is intended to be connected to the high potential.

In principle, it may be advantageous if all the connection surfaces lie next to one another, although not in series, in projection in the normal direction.

It may also be advantageous if a first line section of the first DC voltage terminal element, which is connected directly to the first connection surface, aligns at least in sections with the third connection surface of the third DC voltage terminal element in the normal direction and thus forms there a stack when viewed in the normal direction.

It may also be advantageous if a second line section of the second DC voltage terminal element, which is connected directly to the second connection surface, aligns at least in sections with the third connection surface of the third DC voltage terminal element in the normal direction.

In principle, it may be preferred if all the DC voltage terminal elements are arranged on a first narrow side of the housing when viewed in the normal direction. Likewise, it may be preferred if the AC voltage terminal element is arranged on a second narrow side of the housing when viewed in the normal direction.

It may also be advantageous if a centrally arranged fastening cut-out extends through the switching device.

It may be advantageous if the respective DC voltage terminal elements are in the form of a metal foil or metal sheet, with a thickness of preferably 300 μm to 2000 μm, particularly preferably of 500 μm to 1500 μm.

The object is furthermore achieved according to the invention by a power electronics arrangement with a plurality of three-level power semiconductor modules, wherein all the three-level power semiconductor modules are arranged with their longitudinal sides next to one another in a row and wherein the DC voltage terminal elements of all the power semiconductor modules are preferably likewise arranged in a row.

Here, it may also be advantageous if all the respective DC voltage terminal elements are connected in a polarity-appropriate manner to common, respectively assigned DC voltage supply line elements of a DC voltage supply line device.

It is understood that the different configurations of the invention may be realized individually or in any desired combinations to achieve improvements. In particular, the features mentioned and explained above and hereinafter may be used not only in the specified combinations but also in other combinations or in isolation, without departing from the scope of the present invention and regardless of whether they are disclosed in the context of the three-level power semiconductor module or the arrangement.

The above and other aspects, features, objects, and advantages of the present invention will become apparent from the following description read in conjunction with the accompanying drawings for exemplary but nonlimiting embodiments, in which like reference numerals designate the same elements.

### BRIEF DESCRIPTION OF THE DRAWINGS

FIG. 1 schematically shows a TNPC circuit topology.

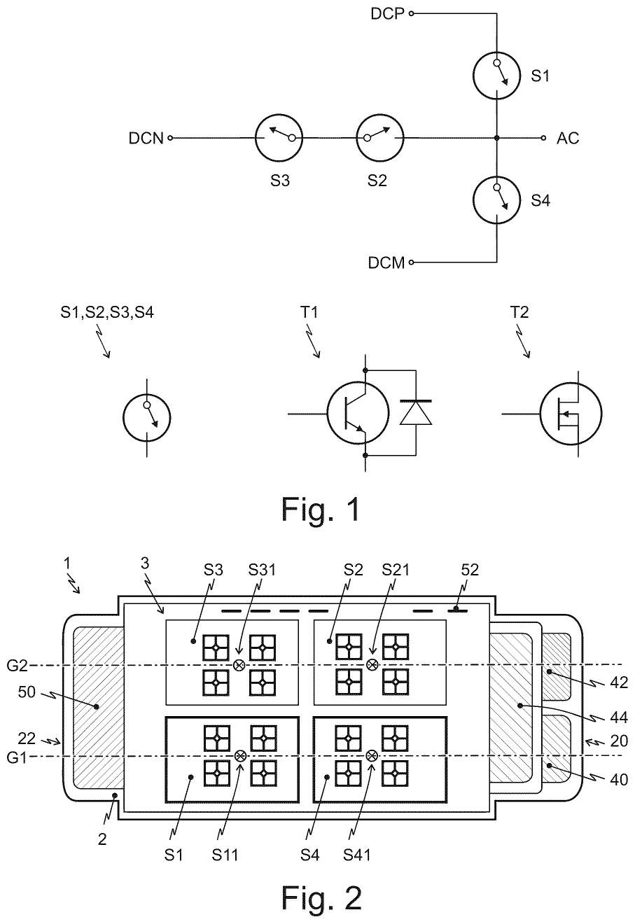

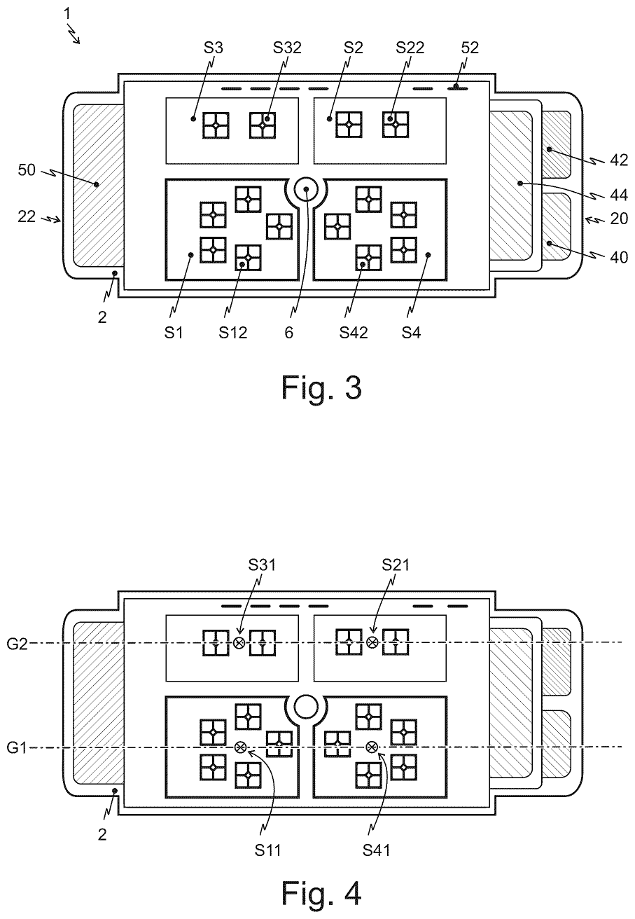

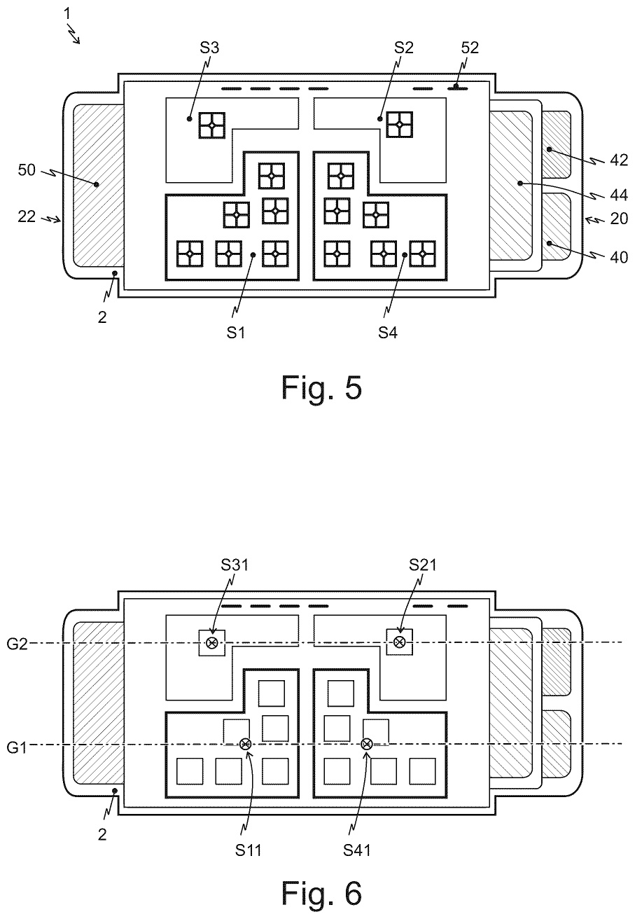

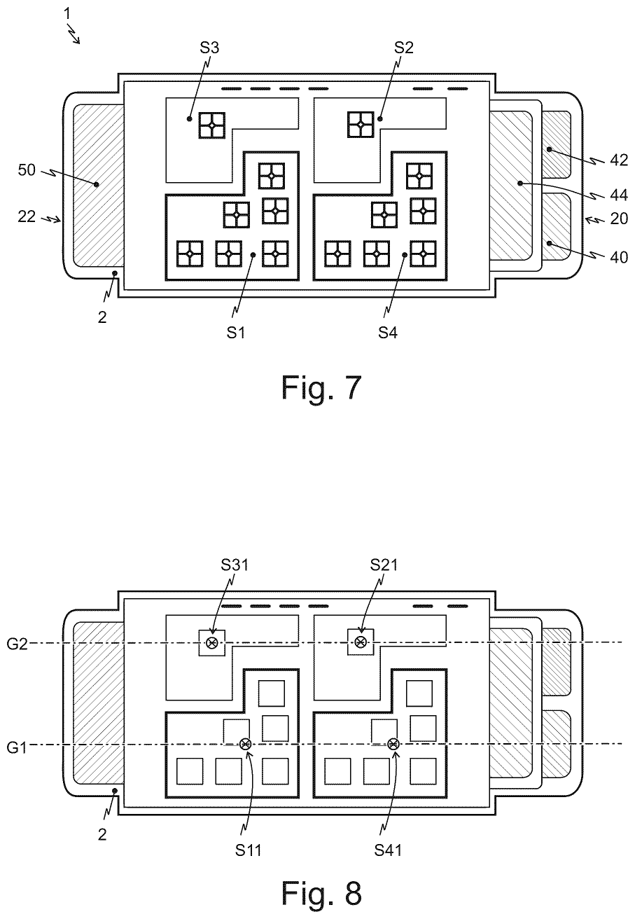

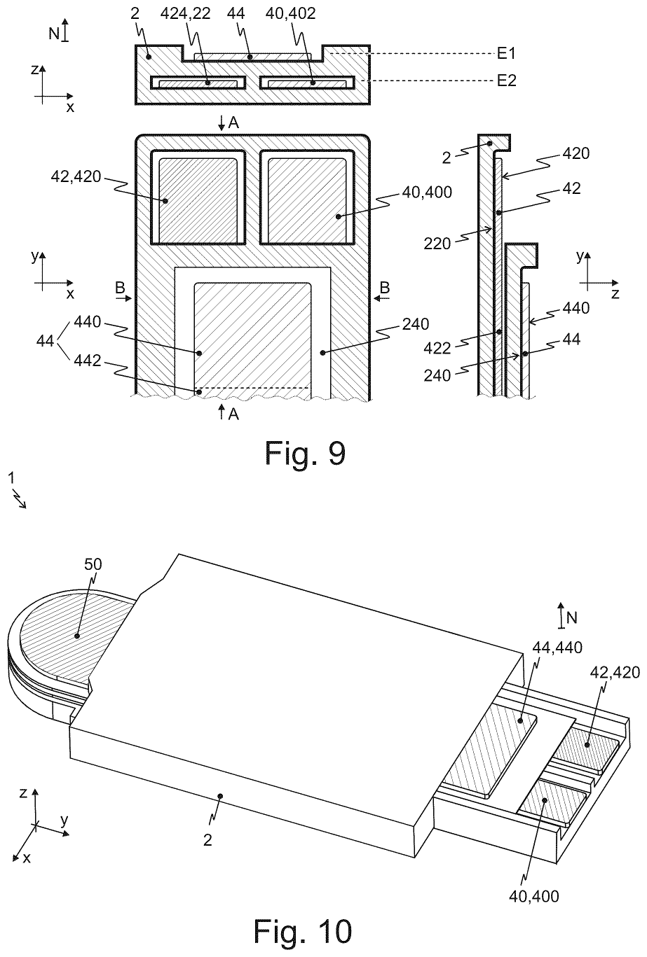

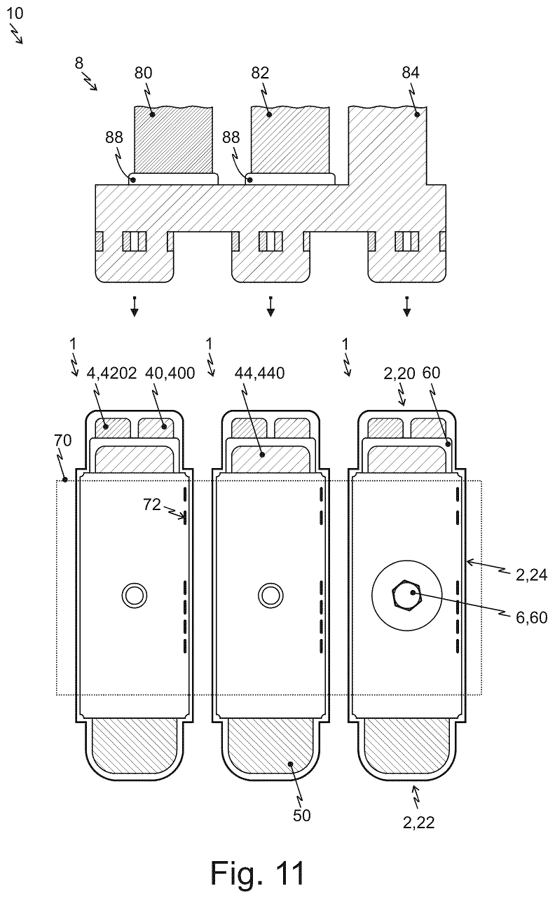

FIG. 2 shows a plan view of a first configuration of a three-level power semiconductor module.

FIGS. 3 and 4 show plan views of a second configuration of a three-level power semiconductor module.

FIGS. 5 and 6 show plan views of a third configuration of a three-level power semiconductor module.

FIGS. 7 and 8 show plan views of a fourth configuration of a three-level power semiconductor module.

FIG. 9 shows a section of the DC voltage terminal elements and of a housing of the first configuration of the three-level power semiconductor module according to the invention.

FIG. 10 shows the first configuration of the three-level power semiconductor module according to the invention in a three-dimensional schematic view.

FIG. 11 shows an arrangement according to the invention.

### DETAILED DESCRIPTION OF THE PREFERRED EMBODIMENTS

Reference will now be made in detail to embodiments of the invention. Wherever possible, same or similar reference numerals are used in the drawings and the description to refer to the same or like parts or steps. The drawings are in simplified form and are not to precise scale. The word ‘couple’ or ‘bond’ or and similar terms do not necessarily denote direct and immediate connections, but also include connections through intermediate elements or devices. For purposes of convenience and clarity only, directional (up/down etc.) or motional (forward/back, etc.) terms may be used with respect to the drawings. These and similar directional terms should not be construed to limit the scope in any manner. It will also be understood that other embodiments may be utilized without departing from the scope of the present invention, and that the detailed description is not to be taken in a limiting sense, and that elements may be differently positioned, or otherwise noted as in the appended claims without requirements of the written description being required thereto.

FIG. 1 shows a configuration of a TNPC (T-type neutral point clamped) circuit topology, in particular a 3-level converter half-bridge. Here, the circuit has a DC branch with an upper first switch S1, wherein the power input of the first switch S1 is connected to a high, in this case positive, potential DCP of a DC voltage source. The DC branch furthermore has a lower fourth switch S4, wherein the power output of the fourth switch S4 is connected to a low, in this case negative, potential DCM of a DC voltage source. The half-bridge circuit has a center tap AC between the first and fourth switch S1, S4. The center tap AC is connected to an AC voltage terminal 50, which has AC potential during operation.

FIG. 1 furthermore depicts a T branch with a second switch S2, wherein in this case by way of example the power output of the second switch S2 is connected directly to the center tap. The T branch also has a third switch S3. The power output of the third power semiconductor switch S3 here is connected directly to an intermediate potential DCN, which is formed as a basic potential here. The power input of the second switch S2 and the power input of the third switch S3 are electrically connected to one another here.

The first, second, third and fourth switch S1, S2, S3, S4 is formed, by way of example here, as an IGBT T1 antiparallel-connected diode or as a parallel circuit of a plurality of IGBTs with antiparallel-connected diodes. The collector terminal of the respective IGBT in this case forms the load input, the emitter terminal forms the load output and the gate terminal forms the control input. The respective power semiconductor switches may alternatively also each be in the form of a MOS-FET T2, preferably a MOS-FET with a large band gap, that is to say a SiC-MOS-FET, or an HEMT or a GaN-HEMT. In addition, a parallel circuit of a plurality of MOS-FETs is possible. Then, the drain terminal forms the load input, the source terminal forms the load output and the gate terminal forms the control input, respectively.

FIG. 2 shows a plan view of a first configuration of a three-level power semiconductor module 1 with a housing 2, with a schematically depicted switching device 3, with a first, a second and a third DC voltage terminal element 40, 42, 44 which form a group, and with an AC voltage terminal element 50. The switching device, more precisely the substrate thereof, has a normal direction N in this case. The switching device 3 itself is in the form of a TNPC circuit arrangement in half-bridge topology, as depicted in FIG. 1. Further details, such as conductor tracks on the substrate, are not depicted for reasons of clarity.

This switching device thus has a DC branch with an upper first switch S1 and with a lower fourth switch S4. It furthermore has a T branch with a second switch S2 and with a third switch S3. Each of these switches S1, S2, S3, S4 is formed by four power semiconductor switches, in this case four MOS-FETs in silicon carbide technology. The respective power semiconductor switches form a group with a focal point. In the case of four identical power semiconductor switches in the corners of a rectangle, this focal point is the center of the rectangle.

According to the invention, the focal points S11, S41 of the first and fourth switch S1, S4 lie on a first straight line G1 which runs in the direction from the group of DC voltage terminals 40, 42, 44 to the AC voltage terminal 50. The focal points S21, S31 of the second and third switch S2, S3 lie on a second straight line G2 which runs in the direction from the group of DC voltage terminals 40, 42, 44 to the AC voltage terminal 50. Both straight lines G1, G2 are parallel to one another in this configuration.

The first DC voltage terminal element 40 of this configuration of a three-level power semiconductor module 1 is intended, purely by way of example, to be connected to the positive potential DCP of a DC voltage source, cf. FIG. 1, while the second DC voltage terminal element 42 is intended to be connected to an intermediate potential DCN and wherein the third DC voltage terminal element 44 is intended to be connected to the negative potential DCM of a DC voltage source (cf. FIG. 1 in each case).

Each of the DC voltage terminal elements 40, 42, 44 has a connection surface 400, 420, 440, which is contactable from the normal direction. For the precise location of the DC voltage terminal elements and the respectively assigned connection surfaces, compare FIG. 9. Thus, the respective connection surfaces 400, 420, 440 of the DC voltage terminal elements 40, 42, 44 point in the same normal direction N, and are arranged next to one another, but not in series, in projection in the normal direction N.

FIGS. 3 and 4 show plan views of a second configuration of a three-level power semiconductor module. This differs from that of FIG. 2 in particular by the configuration of the respective first to fourth switches S1, S2, S3, S4. The first and fourth switch S1, S4 are each formed from five power semiconductor components S12, S14, while the second and third switches S2, S3 are each formed from two power semiconductor components S22, S32.

Again, the focal points S11, S41 of the first and fourth switch S1, S4 are arranged on a first straight line G1 which runs in the direction from the group of DC voltage terminals 40, 42, 44 to the AC voltage terminal 50. The focal points S21, S31 of the second and third switch S2, S3 are arranged on a second straight line which runs in the direction from the group of DC voltage terminals 40, 42, 44 to the AC voltage terminal 50. Both straight lines G1, G2 are also parallel to one another in this configuration.

In addition, the housing 2 still has a continuous cut-out for the arrangement of a fastening device, cf. FIG. 11. Furthermore, the arrangement of all power semiconductor components is mirror-symmetrical to a mirror axis, which is perpendicular to both straight lines and runs through the central cut-out.

FIGS. 5 and 6 show plan views of a third configuration of a three-level power semiconductor module. This differs from that of FIGS. 2 and 3 in particular by the configuration of the respective first to fourth switches S1, S2, S3, S4. The first and fourth switches S1, S4 are each formed from six power semiconductor components, while the second and third switches S2, S3 are each formed from only one power semiconductor component, wherein the focal point of the switch S21, S31 is thus located in the center of the power semiconductor component representing same. This may be advantageous in specific load-dependent control methods of the three-level power semiconductor module 1. Here, there is also a symmetrical position of the power semiconductor component of the switches relative to one another.

FIGS. 7 and 8 show plan views of a fourth configuration of a three-level power semiconductor module 1. This differs from the third configuration in particular by the lack of symmetry. Instead, the first and third switches S1, S3 are in this case identical to the second and fourth switches S2, S4. This is particularly advantageous when the first and third switches S1, S3 are arranged on a substrate and the second and fourth switches S2, S4 are arranged on a further substrate, since then both substrates can be of identical form.

In the third and fourth configuration, the focal points S11, S41 of the first and fourth switch S1, S4 are also arranged on a first straight line G1 which runs in the direction from the group of DC voltage terminals 40, 42, 44 to the AC voltage terminal 50. The focal points S21, S31 of the second and third switch S2, S3 are arranged on a second straight line G2 which runs in the direction from the group of DC voltage terminals 40, 42, 44 to the AC voltage terminal 50. Both straight lines G1, G2 are also parallel to one another in these configurations.

FIG. 9 shows a section of the DC voltage terminal elements 40, 42, 44 and of a housing 2 of the first configuration of the three-level power semiconductor module 1 according to the invention in three orthogonal views. The three DC voltage terminal elements 40, 42, 44 are depicted, the connection surfaces 400, 420, 440 of which all have the same normal direction N, in this case the z direction, and a section of the associated housing 2 is also depicted, cf. also FIG. 10.

In this case, the sectional view above the plan view shows a section along the line B-B and the sectional view next to the plan view shows a section along the line A-A.

The housing 2 is formed as an insulating-material housing, in particular a plastic housing, and has on its first narrow side 20 a first and a second bearing surface 200, 220, respectively. The first DC voltage terminal element 40 is arranged on the first bearing surface 200 and the second DC voltage terminal element 42 is arranged on the second bearing surface 220, wherein these bearing surfaces 200, 220 are also orientated in the normal direction N. The first and the second DC voltage terminal element 40,42 are arranged on one of these bearing surfaces 200, 220, respectively. Their respective connection surfaces 400, 420 thus lie in a second plane E2 and are arranged next to one another there.

The housing 2 furthermore has a third bearing surface 240 for the third DC voltage terminal element 44, wherein this third bearing surface 240 is also orientated in the normal direction N. The third DC voltage terminal element 44 is arranged on this third bearing surface 240, and therefore its third connection surface 440 is also orientated in the normal direction N. Thus, all the connection surfaces 400, 420, 440 of the DC voltage terminal elements 40, 42, 44 are orientated in the normal direction N. In addition, the bearing surface 240 of the third DC voltage terminal element 44 is set back in the negative y direction and arranged in a first plane E1, parallel to the second, which is arranged in the negative normal direction N, that is to say also in the negative z direction above the second plane E2. With this configuration of the housing 2 and with this arrangement of the DC voltage terminal elements 40, 42, 44, all three connection surfaces 400, 420, 440 of the three DC voltage terminal elements 40, 42, 44 lie next to one another, although not in a row.

This means that a first line section 402 of the first DC voltage terminal element 40, which is connected directly to the first connection surface 400, aligns in sections with the third connection surface 440 of the third DC voltage terminal element 44 in the normal direction N. Simultaneously and symmetrically thereto, a second line section 422 of the second DC voltage terminal element 42, which is connected directly to the second connection surface 420, aligns in sections with the third connection surface 440 of the third DC voltage terminal element 44 in the normal direction N.

This configuration results in a low-inductance configuration in each case both for the combination of first and third DC voltage terminal element 40, 44 and for the combination of second and third DC voltage terminal element 42, 44.

Of course the housing 2 or additional insulation elements in conjunction with the housing are formed in such a way that the respective DC voltage terminal elements are arranged in a manner sufficiently electrically insulated from one another.

FIG. 10 shows the first configuration of the three-level power semiconductor module 1 according to the invention in a three-dimensional schematic view. A substantially cuboid housing 2 is depicted, wherein all the DC voltage terminal elements 40, 42, 44 are arranged on its first narrow side 20, while the AC voltage terminal element 50 is arranged on a second narrow side 22. This configuration allows several three-level power semiconductor modules 1 to be arranged next to one another in a very space-saving manner, cf. FIG. 11.

The specific configuration and arrangement of the DC voltage terminal elements 40, 42, 44 corresponds to that of FIG. 9.

The DC voltage terminal elements 40, 42, 44 and the AC voltage terminal element 50 of this three-level power semiconductor module 1 are formed as a metal sheet, having a thickness of 1 mm.

FIG. 11 shows an arrangement according to the invention, wherein three three-level power semiconductor modules 1 are arranged with their longitudinal sides 24 next to one another here. In this case, the DC voltage terminal elements 40, 42, 44 of all the three-level power semiconductor modules 1 are arranged on the same, the first, narrow side 20.

Furthermore, three DC voltage supply line elements 80, 82, 84 are depicted, which are arranged stacked in sections and form the DC voltage supply line 8 of a capacitor device which is not depicted. For reasons of clarity, the DC voltage supply line elements 80, 82, 84 are spaced apart from the three-level power semiconductor modules 1. The respective DC voltage supply line element 80, 82, 84 is connected in a polarity-appropriate manner to a respectively assigned DC voltage terminal element 40, 42, 44.

Of course, both the DC voltage terminal elements 40, 42, 44 and the DC voltage supply line elements 80, 82, 84 have an insulation device 60, 88 for electrically insulating the elements of differing polarity.

Furthermore, two of the DC voltage supply line elements 82, 84 have cut-outs which are designed and intended for a laser beam acting from a negative normal direction N to be able to act upon a DC voltage supply line element 80, 82, arranged therebelow, through these cut-outs. A laser-welded connection formed in this way results in a permanently materially-bonded connection between a DC voltage supply line element and an assigned DC voltage terminal element in each case.

Each three-level power semiconductor module 1 furthermore has auxiliary terminal elements 72, cf. also FIGS. 2 to 8, which are each arranged along one or both longitudinal sides. These auxiliary terminal elements 72 are used for electrically conductive connection to a driver device 70 common to all power semiconductor modules 2, 4. This covers, in each case partially, all three-level power semiconductor modules 1.

Each three-level power semiconductor module 1 has a centrally arranged fastening cut-out 6, which extends through the switching device 3 and further components following in the normal direction N. A section of a fastening device 60, in particular a screw, which attaches the respective three-level power semiconductor module 1 on a cooling device, not depicted, preferably a liquid cooling device, is arranged in said fastening cut-out 6.

Also, the inventors intend that only those claims which use the specific and exact phrase “means for” are intended to be interpreted under 35 USC 112. The structure, device, and arrangement herein is noted and well supported in the entire disclosure. Moreover, no limitations from the specification are intended to be read into any claims, unless those limitations are expressly included in the claims.

Having described at least one of the preferred embodiments of the present invention with reference to the accompanying drawings, it will be apparent to those skills that the invention is not limited to those precise embodiments, and that various modifications and variations can be made in the presently disclosed system without departing from the scope or spirit of the invention. Thus, it is intended that the present disclosure covers modifications and variations of this disclosure provided they come within the scope of the appended claims and their equivalents.

What is claimed is:

1. A three-level power semiconductor module (1), comprising:
a housing (2), with a switching device (3), with a first, a second and a third DC voltage terminal element (40, 42, 44) which form a group, and with an AC voltage terminal element (50);
the switching device (3) has a normal direction (N) and is in the form of a TNPC circuit arrangement, which has a DC branch with an upper first switch (S1) whose power input is connected to a high potential (DCP) of a DC voltage source, with a lower fourth switch (S4) whose power output is connected to a low potential (DCM) of a DC voltage source and with a center tap (AC) and a T branch with a second switch (S2) whose power input is connected indirectly or directly to an intermediate potential (DCN) and with a third switch (S3), connected in series with the second switch (S2), whose power input is connected indirectly or directly to the center tap (AC);
wherein the focal points (S11, S41) of the first and fourth switch (S1, S4) lie in the direction from the group of DC voltage terminals (40, 42, 44) to the AC voltage terminal (50) on a first straight line (G1); and
the focal points (S21, S31) of the second and third switch (S2, S3) lie in the direction from the group of DC voltage terminals (40, 42, 44) to the AC voltage terminal (50) on a second straight line (G2) adjacent to the first straight line.

2. The three-level power semiconductor module, according to claim 1, wherein:
the current-carrying capacity of all the switches (S1, S2, S3) is identical or the current-carrying capacity of the first and fourth switch (S1, S4) is greater than that of the second and third switch (S2, S3), respectively.

3. The three-level power semiconductor module, according to claim 1, wherein:
each said respective switch (S1, S2, S3, S4) is in the form of a power semiconductor component or a group of power semiconductor components connected in parallel;
wherein the respective power semiconductor component is in the form of at least one of an IGBT, an IGBT with antiparallel-connected diodes, a MOS-FET, a SiC-MOS-FET, an HEMT, and a GaN-HEMT.

4. The three-level power semiconductor module, according to claim 1, wherein:
each of the respective focal points (S11, S21, S31, S41) form the corners of a trapezoid or a parallelogram.

5. The three-level power semiconductor module, according to claim 1, wherein:
each of the respective connection surfaces (400, 420, 440) of the DC voltage terminal elements (40, 42, 44) has an identical normal direction (N) and are arranged next to one another in projection in the normal direction (N); and
wherein the third connection surface (440) of the third DC voltage terminal element (44) lies in a first plane (E1) and the first connection surface (400) of the first DC voltage terminal element (42) lies in a second plane (E2) parallel to the first when viewed in the normal direction (N).

6. The three-level power semiconductor module, according to claim 5, wherein:
the second connection surface (420) of the second DC voltage terminal element (42) lies in the second plane (E2) when viewed in the normal direction (N).

7. The three-level power semiconductor module, according to claim 5, wherein:
the first DC voltage terminal element (40) is connected to the high potential (DCP);
the second DC voltage terminal element (42) is connected to the intermediate potential (DCN); and
the third DC voltage terminal element (44) is connected to the low potential (DCM).

8. The three-level power semiconductor module, according to claim 5, wherein:
the first DC voltage terminal element (40) is connected to the low potential (DCM);
the second DC voltage terminal element (42) is connected to the intermediate potential (DCN);
the third DC voltage terminal element (44) is connected to the high potential (DCP).

9. The three-level power semiconductor module, according to claim 1, wherein:
each of the connection surfaces (400, 420, 440) lie next to one another, not in series, and in projection in the normal direction (N).

10. The three-level power semiconductor module, according to claim 5, wherein:
a first line section (402) of the first DC voltage terminal element (40) is connected directly to the first connection surface (400) and aligns at least in sections with the third connection surface (440) of the third DC voltage terminal element (44) in the normal direction (N).

11. The three-level power semiconductor module, according to claim 5, wherein:
a second line section (422) of the second DC voltage terminal element (42) is connected directly to the second connection surface (420) and aligns at least in sections with the third connection surface (440) of the third DC voltage terminal element (44) in the normal direction (N).

12. The three-level power semiconductor module, according to claim 1, wherein:
each of the DC voltage terminal elements (40, 42, 44) are arranged on a first narrow side (20) of the housing (2).

13. The three-level power semiconductor module, according to claim 1, wherein:
the AC voltage terminal element (50) is arranged on a second narrow side (22) of the housing (2).

14. The three-level power semiconductor module, according to claim 1, wherein:
a centrally arranged fastening cut-out (6) extends through the switching device.

15. A power electronics arrangement (10), comprising:
a plurality of three-level power semiconductor modules (1), according to claim 1, wherein:
each of the three-level power semiconductor modules (1) are arranged with their longitudinal sides (24) next to one another in a row, and
each of the DC voltage terminal elements (40, 42, 44) of the each of the three-level power semiconductor modules (1) are arranged in a row.

16. The power electronics arrangement, according to claim 15, wherein:
each of the respective DC voltage terminal elements (40, 42, 44) are connected in a polarity-appropriate manner to common, respectively assigned DC voltage supply line elements (80, 82, 84) of a DC voltage supply line device (8).
